(19) United States
(12) Patent Application Publication
(10) Pub. No.: US 2017/0346039 A1
(43) Pub. Date: Nov. 30, 2017

(54) SEMICONDUCTOR DEVICE SUBSTRATE AND DISPLAY UNIT

(71) Applicant: JOLED INC., Tokyo (JP)

(72) Inventor: Yuichi KATO, Tokyo (JP)

(21) Appl. No.: 15/589,901

(22) Filed: May 8, 2017

(30) Foreign Application Priority Data
May 26, 2016 (JP) 2016-105355

(51) Int. Cl. H01L 51/52; H01L 27/32

(52) U.S. Cl. CPC H01L 51/5253; H01L 27/3276; H01L 27/3211; H01L 27/322

(57) ABSTRACT

A semiconductor device substrate includes a substrate, a first inorganic material layer, and a functional layer. The first inorganic material layer is provided on the substrate. The first inorganic material layer has a moisture barrier property. The functional layer is provided on the first inorganic material layer. The functional layer contains an organic material and has a detachment-suppressing function.

### CROSS REFERENCE TO RELATED APPLICATIONS

The present application claims priority from Japanese Patent Application No. 2016-105355 filed on May 26, 2016, the entire contents of which are hereby incorporated by reference.

### BACKGROUND

The disclosure relates to a semiconductor device substrate to be used as a moisture barrier of a semiconductor device, and a display unit including the semiconductor device substrate.

A semiconductor device with use of a flexible panel, for example, is provided with a moisture barrier in order to prevent moisture from entering a front plane and a back plane. The moisture barrier has a configuration in which an inorganic film and an organic film are stacked. For example, reference is made to Japanese Unexamined Patent Application Publication (Published Japanese Translation of PCT Application) No. JP2002-532850.

### SUMMARY

A moisture barrier allows for improvement of a barrier performance by stacking an organic film on an inorganic film, but is inferior in adhesion between films, causing the films to be easily detached from each other. As a result, the barrier performance is lowered, thus leading to a defect or lowering in characteristics of a semiconductor device.

It is desirable to provide a semiconductor device substrate and a display unit that allow for improvement of the barrier performance.

A semiconductor device substrate according to an embodiment of the disclosure includes a substrate, a first inorganic material layer, and a functional layer. The first inorganic material layer is provided on the substrate. The first inorganic material layer has a moisture barrier property. The functional layer is provided on the first inorganic material layer. The functional layer contains an organic material and has a detachment-suppressing function.

A display unit according to an embodiment of the disclosure includes a substrate, a first barrier film, and an element section. The first barrier film is provided on the substrate and has a moisture barrier property. The element section is provided on the first barrier film and includes a plurality of pixels. The first barrier film includes a first inorganic material layer and a functional layer in order from the substrate. The first inorganic material layer has the moisture barrier property. The functional layer is provided on the first inorganic material layer. The functional layer contains an organic material and has a detachment-suppressing function.

It is to be noted that that the contents described above are mere examples of the disclosure. The effects of the disclosure are not limited to those described above, and may be other different effects, or may further include other effects in addition to the effects described above.

### BRIEF DESCRIPTION OF THE DRAWINGS

The accompanying drawings are included to provide a further understanding of the disclosure, and are incorporated in and constitute a part of this specification. The drawings illustrate example embodiments and, together with the specification, serve to explain the principles of the technology.

FIG. 1 is a cross-sectional view of a schematic configuration of a display unit according to a first embodiment of the disclosure.

FIG. 2 is a cross-sectional view of a detailed configuration of the display unit illustrated in FIG. 1.

FIG. 3 is a cross-sectional view of a configuration example of a barrier substrate illustrated in FIGS. 1 and 2.

FIG. 4 is a cross-sectional view of a configuration example of a second barrier film illustrated in FIG. 2.

FIG. 5 is a cross-sectional view of a configuration of a barrier substrate according to a comparative example.

FIG. 6 is a cross-sectional view of a configuration example of a barrier substrate according to a second embodiment of the disclosure.

FIG. 7 is a cross-sectional view of a configuration example of a barrier substrate according to Modification Example 1.

FIG. 8 is a cross-sectional view of a configuration example of a barrier substrate according to Modification Example 2.

FIG. 9 is a cross-sectional view of a configuration example of a display unit according to Modification Example 3.

### DETAILED DESCRIPTION

Some example embodiments of the disclosure are described below in detail, in the following order, with reference to the accompanying drawings.

1. First Embodiment (An example of a barrier substrate in which a functional layer including a layered film of a detachment-suppressing layer and an organic planarization layer is provided on an inorganic material layer, and of a display unit)
2. Second Embodiment (An example where the functional layer is an organic planarization layer containing silicon)
3. Modification Example 1 (An example where the functional layer includes a layered film of a detachment-suppressing layer and an organic planarization layer containing silicon)
4. Modification Example 2 (An example where the detachment-suppressing layer is provided only in selective regions)
5. Modification Example 3 (Another configuration example of a second barrier film)

### 1. First Embodiment

### [Configuration]

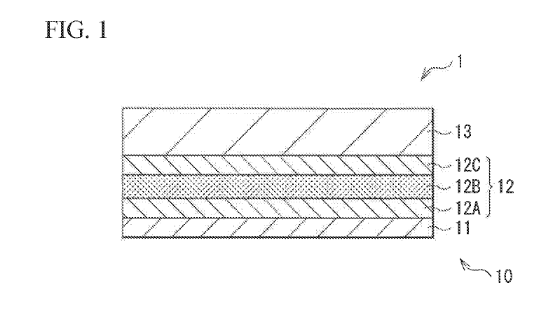

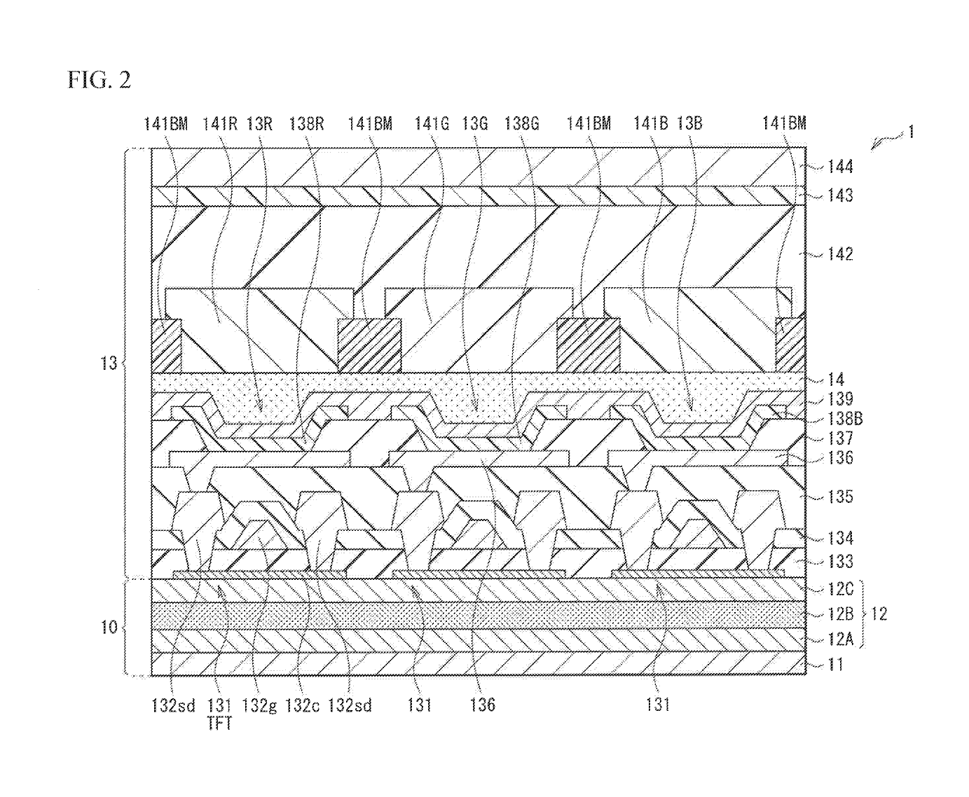

FIG. 1 is a cross-sectional view of a configuration of a display unit (display unit 1) according to an embodiment of the disclosure. FIG. 2 is a cross-sectional view of a detailed configuration of the display unit 1. The display unit 1 may be, for example, an organic electroluminescence (EL) display with use of an organic electroluminescence element, and may be, for example, a top surface emission (top emission) display unit that emits light of any color of R (red), G (green), and B (blue) from a top surface. The display unit 1 may include an element section 13 on a barrier substrate 10, for example.

The barrier substrate 10 may have roles of supporting the element section 13, and of preventing moisture from entering the element section 13. In the barrier substrate 10, a first barrier film 12 (first barrier film) may be provided on a support substrate 11, for example. The first barrier film 12 may be, for example, a layered film including an inorganic material layer 12A (first inorganic material layer), a functional layer 12B, and an inorganic material layer 12C (second inorganic material layer) in order from the support substrate 11. It is to be noted that the barrier substrate 10 corresponds to a specific but non-limiting example of the “semiconductor device substrate” according to an embodiment of the disclosure. Further, description is given in the present embodiment by exemplifying a case where the barrier substrate 10 (semiconductor device substrate) is applied to the display unit 1. However, application of the barrier substrate 10 is not limited to the display unit 1, but is applicable to other various semiconductor devices, for example, an imaging unit such as an image sensor. However, the barrier substrate 10 may be more preferably used for a semiconductor device including an element susceptible to moisture, i.e., an element likely to undergo deterioration of characteristics due to entering of moisture. For example, the barrier substrate 10 may be more preferably used for a semiconductor device including the organic electroluminescence element and an active element with use of an oxide semiconductor or a low-temperature polycrystalline silicon (LTPS). Specific configuration of the barrier substrate 10 is described later.

The element section 13 may include, for example, a plurality of pixels that are arranged two-dimensionally, and may display an image on the basis of an image signal supplied from the outside by an active matrix method, for example. More specifically, in the element section 13, each of the pixels may be configured by a pixel circuit including a thin-film transistor (TFT) 131, and an organic electroluminescence element (any of organic EL elements 13R, 13G, and 13B).

A plurality of scanning lines extending in a row direction of a pixel arrangement, a plurality of signal lines extending in a column direction, and a plurality of power lines extending in the row direction may be coupled to the respective pixels. Each of the pixels may be display-driven by a scanning line drive circuit, a signal line drive circuit, and a power line drive circuit through the scanning line, the signal line, and the power line, respectively.

### (Detailed Configuration of Element Section 13)

In the element section 13, a pixel circuit including the TFT 131 may be provided on the barrier substrate 10. A plurality of organic EL elements 13R, 13G, and 13B may be disposed two-dimensionally on the pixel circuit including the TFT 131, with a planarization layer 135 being interposed therebetween. A second barrier film 14, for example, may be provided on the organic EL elements 13R, 13G, and 13B. Color filter layers 141R, 141G, and 141B as well as a black matrix layer 141BM may be provided on the second barrier film 14. A second substrate 144 may be joined onto the color filter layers 141R, 141G, and 141B as well as the black matrix layer 141BM, with an overcoat layer 142 and an adhesive layer 143 being interposed therebetween.

The TFT 131 may include a semiconductor layer 132c in a selective region on the barrier substrate 10, and may include a gate electrode 132g on the semiconductor layer 132c with a gate insulating film 133 interposed therebetween. An interlayer insulating film 134 may be provided on the gate electrode 132g. A pair of source-drain electrodes 132sd may be provided on the interlayer insulating film 134. The source-drain electrodes 132sd may be electrically coupled to the semiconductor layer 132c through a contact hole provided in the interlayer insulating film 134. One of electrodes of the source-drain electrodes 132sd may be electrically coupled to a first electrode 136 of the organic EL element 13R (or each of organic EL elements 13G and 13B) through a contact portion c1.

The semiconductor layer 132c may be made of an oxide semiconductor, low-temperature polycrystalline silicon, an organic semiconductor, high-temperature polycrystalline silicon, microcrystalline silicon, or non-crystalline silicon, for example. The gate electrode 132g may be made of one or more of molybdenum (Mo), copper (Cu), and aluminum (Al), for example. The gate insulating film 133 and the interlayer insulating film 134 may be each made of an inorganic material such as silicon oxide (SiO₂), silicon nitride (SiN), and silicon oxynitride (SiON), for example. The source-drain electrodes 132sd may function as a source or a drain, and may be each made of one or more of molybdenum (Mo), copper (Cu), and aluminum (Al), for example. The gate electrode 132g and the source-drain electrodes 132sd may be each made of a transparent electrically-conductive film such as indium-tin oxide (ITO) and indium-zinc oxide (IZO). A material for each of the gate insulating film 133 and the interlayer insulating film 134 is not limited to the above-mentioned inorganic material; the gate insulating film 133 and the interlayer insulating film 134 may also be made of an organic material.

As the TFT 131, a top gate element structure is exemplified in this example; however, the element structure of the TFT 131 is not limited thereto, and may be a bottom gate element structure, for example. Alternatively, either a single gate element structure or a dual gate element structure may also be adopted.

The organic EL element 13R may include an organic layer 138R including a red light-emitting layer between the first electrode 136 and a second electrode 139. Likewise, the organic EL element 13G may include an organic layer 138G including a green light-emitting layer between the first electrode 136 and the second electrode 139. The organic EL element 13B may include an organic layer 138B including a blue light-emitting layer between the first electrode 136 and the second electrode 139.

The first electrode 136 may function as an anode, for example, and may be provided for each pixel (for each organic EL element). Examples of a constituent material of the first electrode 136 may include a simple substance and an alloy of metal elements such as chromium (Cr), gold (Au), platinum (Pt), nickel (Ni), copper (Cu), tungsten (W), and silver (Ag). Further, the first electrode 136 may include a layered film of a metal film and an electrically conductive material having light-transmissivity (transparent electrically-conductive film). The metal film is made of the simple substance or the alloy of the metal elements. Example of the transparent electrically-conductive film may include indium-tin oxide (ITO), indium-zinc oxide (IZO), and a zinc oxide (ZnO)-based material. Examples of the zinc oxide-based material may include zinc oxide with aluminum (Al) being added thereto (AZO) and zinc oxide with gallium (Ga) being added thereto (GZO).

The organic layers 138R, 138G, and 138B may each include an organic electroluminescence layer (red electroluminescence layer, green electroluminescence layer, or blue electroluminescence layer) that causes recombination of electrons and holes by means of application of an electric field, thus emitting a color light beam of any of R, G, and B. Examples of a film-forming method of the organic layers 138R, 138G, and 138B may include a vacuum deposition method, a printing method, and a coating method. The organic layers 138R, 138G, and 138B may each include, for example, a hole injection layer, a hole transport layer, and an electron transport layer, as necessary, in addition to the organic electroluminescence layer. Further, an electron injection layer may also be provided between the second electrode 139 and each of the organic layers 138R, 138G, and 138B. It is to be noted that, although the organic layers 138R, 138G, and 138B including, respectively, the red light-emitting layer, the green light-emitting layer, and the blue light-emitting layer are provided for each pixel in this example, it is also possible to provide, as a common layer for each pixel, an organic layer including a white light-emitting layer.

The second electrode 139 may function as a cathode, for example, and may be provided (as a common electrode for all the pixels) throughout the entire element section 13. The second electrode 139 may be made of a transparent electrically-conductive film, for example. Examples of a material for the transparent electrically-conductive film may include indium-tin oxide (ITO), indium-zinc oxide (IZO), and a zinc oxide (ZnO)-based material. Examples of the zinc oxide (ZnO)-based material may include zinc oxide with aluminum (Al) being added thereto (AZO) and zinc oxide with gallium (Ga) being added thereto (GZO). The thickness of the second electrode 139 is not particularly limited, and may be set in consideration of electrical conductivity and light-transmissivity. In addition to those mentioned above, an alloy of magnesium and silver (Mg—Ag alloy) may also be used for the second electrode 139.

The organic layers 138R, 138G, and 138B of the respective organic EL elements 13R, 13G, and 13B may be each provided in a region (opening) defined by a pixel separation film 137. The pixel separation film 137 may be provided on the first electrode 136, and may have an opening to face the first electrode 136. The pixel separation film 137 may be made of, for example, a photosensitive resin such as an acrylic resin, a polyimide-based resin, a fluorine-based resin, a silicon-based resin, a fluorine-based polymer, a silicon-based polymer, a novolak-based resin, an epoxy-based resin, and a norbornene-based resin. Alternatively, any of these resin materials with a pigment being dispersed therein may also be used. In addition, it is also possible to use, for example, an inorganic material such as silicon oxide (SiO₂), silicon nitride (SiN), and silicon oxynitride (SiON) for the pixel separation film 137.

The second barrier film 14 (second barrier film) may be provided, for example, above the organic EL elements 13R, 13G, and 13B inside the element section 13 in order to prevent moisture from entering the organic EL elements 13R, 13G, and 13B. A specific configuration of the second barrier film 14 is described later.

The color filter layers 141R, 141G, and 141B may be provided to face the organic EL elements 13R, 13G, and 13B, respectively. The black matrix layer 141BM may be provided in a region between pixels. The color filter layers 141R, 141G, and 141B may be each made of a resin mixed with a pigment. The black matrix 141BM may be configured by, for example, a resin film mixed with a black coloring agent, or a thin film filter utilizing interference of a thin film. The thin film filter may have a configuration in which one or more layers of a thin film made of, for example, metal, metal nitride, or metal oxide are stacked, and may attenuate light utilizing interference of the thin film. Specific but non-limiting examples of the thin film filter may include an alternate layer of Cr and chromium(III) oxide (Cr₂O₃). It is to be noted that it is sufficient for the color filter layers 141R, 141G, and 141B to be disposed as necessary; the color filter layers 141R, 141G, and 141B may not necessarily be disposed. However, providing the color filter layers 141R, 141G, and 141B allows for extraction of light generated at the organic EL elements 13R, 13G, and 13B, as well as absorption of other stray light or outside light, thus enabling the contrast to be improved.

The overcoat layer 142 may be provided for protecting and planarizing a surface of each of the color filter layers 141R, 141G, and 141B and the black matrix layer 141BM. Examples of a constituent material of the overcoat layer 142 may include an acrylic resin, a polyimide-based resin, a fluorine-based resin, a silicon-based resin, a novolak-based resin, an epoxy-based resin, and a norbornene-based resin. Alternatively, any of these resin materials with a pigment being dispersed therein may also be used.

The adhesive layer 143 may be made of, for example, a resin material such as an acrylic resin, a polyimide-based resin, a fluorine-based resin, a silicon-based resin, a novolak-based resin, an epoxy-based resin, and a norbornene-based resin.

The second substrate 144 may be made of a material transparent to the light generated at the organic EL elements 13R, 13G, and 13B, for example, glass or plastic.

### (Detailed Configuration of Barrier Substrate 10)

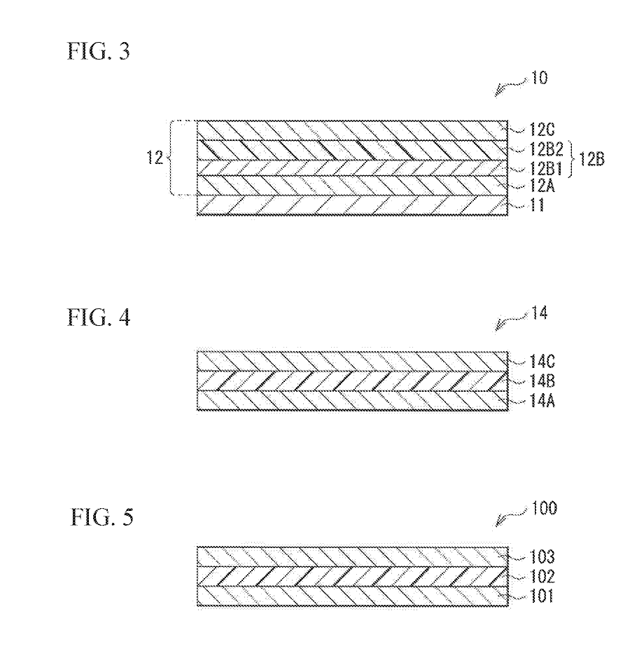

FIG. 3 illustrates a cross-sectional configuration of the barrier substrate 10. As illustrated, the barrier substrate 10 may have a configuration in which the inorganic material layer 12A, the functional layer 12B, and the inorganic material layer 12C are stacked in this order on the support substrate 11. In the present embodiment, the functional layer 12B may be configured by a layered film of a detachment-suppressing layer 12B1 and an organic planarization layer 12B2.

The support substrate 11 may be made of, for example, an inorganic material or an organic material. Examples of the inorganic material may include glass, quartz, silicon, and metal. Examples of the metal to be used for the support substrate 11 may include stainless steel (SUS), aluminum (Al), and copper (Cu). A surface of the metal may be subjected to an insulation treatment. Examples of the organic material may include plastic such as polyimide (PI), polyethylene terephthalate (PET), polyether sulfone (PES), polyethylene naphthalate (PEN), and polycarbonate (PC).

The support substrate 11 may have either flexibility or rigidity. However, the barrier substrate 10 of the present embodiment includes the functional layer 12B having a detachment-suppressing function, and thus exhibits resistance against bending stress in a flexible device. Therefore, the barrier substrate 10 is especially useful in a case where the support substrate 11 has flexibility.

The inorganic material layer 12A may be made of an inorganic material having a moisture barrier property. Examples of such an inorganic material may include silicon oxide (SiO₂), silicon nitride (SiN), silicon oxynitride (SiON), and aluminum oxide (Al₂O₃). The inorganic material layer 12A either may be a monolayer film made of any of the above-mentioned materials, or may be a layered film made of two or more of the above-mentioned materials. The inorganic material layer 12A may have a thickness in a range from 50 nm to 5,000 nm, for example. The inorganic material layer 12A may be formed by any of a plasma-enhanced chemical vapor deposition (PECVD) method, an atomic layer deposition (ALD) method, and a sputtering method, for example.

The functional layer 12B is made of an organic material, and has the detachment-suppressing function. In the present embodiment, the functional layer 12B may include the detachment-suppressing layer 12B1 and the organic planarization layer 12B2 (first organic planarization layer) in order from the inorganic material layer 12A.

The detachment-suppressing layer 12B1 may be provided for suppressing detachment from the inorganic material layer 12A. In other words, the detachment-suppressing layer 12B1 may be provided for enhancing adhesion to the inorganic material layer 12A. The detachment-suppressing layer 12B1 may include one or both of metal and metal oxide, for example. It is preferable to use, for the detachment-suppressing layer 12B1, a material having high adhesion to both of the inorganic material layer 12A and the organic planarization layer 12B2. Example of such a material may include titanium (Ti), titanium oxide (TiOₓ), aluminum (Al), aluminum oxide (Al₂O₃), indium-zinc oxide (IZO), and indium-tin oxide (ITO). The detachment-suppressing layer 12B1 either may be a monolayer film made of any of the above-mentioned materials, or may be a layered film made of two or more thereof. In order to enhance the adhesion, however, the monolayer film may be preferable. The detachment-suppressing layer 12B1 may be formed throughout an entire surface of the inorganic material layer 12A, for example, by any of a chemical vapor deposition (CVD) method and the ALD method, for example.

The thickness of the detachment-suppressing layer 12B1 is not particularly limited; however, the detachment-suppressing layer 12B1 may preferably have a thickness of 10 nm or less when it is configured by a metal film such as a titanium film and an aluminum film, for example. This is because the thickness of more than 10 nm in the case where the detachment-suppressing layer 12B1 is a metal film may sometimes cause the organic planarization layer 12B2 to be detached from an oxide film formed on a surface of the metal film. In addition, it was able to be confirmed from tests such as a cross-cut test and a 90° peel test that thickness of 10 nm or less enables prevention of detachment.

The organic planarization layer 12B2 may be made of an organic material, and may be provided for planarizing a surface of the inorganic material layer 12A. The organic material to be used for the organic planarization layer 12B2 may preferably have heat resistance. This is because the organic material may go through a high-temperature process in a step of forming the above-described element section 13 (specifically, in each step of forming the TFT 131 and the organic EL elements 13R, 13G, and 13B), for example, when forming the element section 13 on the barrier substrate 10 in a process of manufacturing the display unit 1. For example, the organic material to be used for the organic planarization layer 12B2 may preferably have a heat resistance of 400° C. or higher. One example thereof may be polyimide (PI) having a heat resistance in a range from 400° C. to 500° C.

The organic planarization layer 12B2 may have a thickness in a range from 5 μm to 20 μm, for example. The organic planarization layer 12B2 may be formed, for example, by any of various coating methods such as a slit coating method, a spray coating method, and a nozzle coating method.

The inorganic material layer 12C may be made of an inorganic material having a moisture barrier property, as with the inorganic material layer 12A. Examples of such an inorganic material may include silicon oxide, silicon nitride, silicon oxynitride, and aluminum oxide. The inorganic material layer 12C may be a monolayer film made of any of the above-mentioned materials, or may be a layered film made of two or more of the above-mentioned materials. The inorganic material layer 12C may have a thickness in a range from 50 nm to 5,000 nm, for example. The material and the thickness of the inorganic material layer 12C either may be the same as or different from those of the inorganic material layer 12A. The inorganic material layer 12C may not necessarily be provided; however, providing the inorganic material layers 12A and 12C with the functional layer 12B being interposed therebetween makes it possible to further enhance a barrier performance in the first barrier film 12.

It is to be noted that, although the first barrier film 12 is formed as a layered film configured by the inorganic material layer 12A, the functional layer 12B, and the inorganic material layer 12C in this example, it is also possible to further interpose another layer between the layers. Further, although the functional layer 12B is formed as a layered film of the detachment-suppressing layer 12B1 and the organic planarization layer 12B2, it is also possible to further interpose another layer between the detachment-suppressing layer 12B1 and the organic planarization layer 12B2 unless the detachment-suppressing function of the functional layer 12B is significantly impaired.

The element section 13 including the second barrier film 14 may be formed on the barrier substrate 10 including such a first barrier film 12. This prevents moisture from entering, for example, the organic EL elements 13R, 13G, and 13B as well as the TFT 131 provided in the element section 13 from a back plane and a front plane.

FIG. 4 illustrates a configuration example of the second barrier film 14. As illustrated, the second barrier film 14 may have a configuration in which, for example, on an inorganic material layer 14A (third inorganic material layer) are provided an organic planarization layer 14B (third organic planarization layer) and an inorganic material layer 14C (fourth inorganic material layer). The layers of the second barrier film 14 may be formed sequentially, for example, on each of the organic EL elements 13R, 13G, and 13B.

The inorganic material layers 14A and 14C may be made of an inorganic material having a moisture barrier property, for example, silicon oxide, silicon nitride, silicon oxynitride, and aluminum oxide, as with the inorganic material layer 12A. The inorganic material layer 14A may have a thickness in a range from 50 nm to 5,000 nm, for example. The materials and the thicknesses of the inorganic material layers 14A and 14C either may be the same as or different from each other. Further, the inorganic material layer 14C may not necessarily be provided; however, providing the inorganic material layers 14A and 14C with the organic planarization layer 14B being interposed therebetween makes it possible to further enhance a barrier performance in the second barrier film 14.

The organic planarization layer 14B may be made of an organic material. Here, the second barrier film 14 may be formed after formation of the TFT 131 and the organic EL elements 13R, 13G, and 13B. Therefore, it is not questioned whether the material has heat resistance for the organic planarization layer 14B of the second barrier film 14, unlike the organic planarization layer 12B2 of the first barrier film 12. Consequently, the organic planarization layer 14B has higher degree of freedom of material choice than that of the organic planarization layer 12B2.

### [Workings and Effects]

In the display unit 1 as described above, when a drive current is injected into the organic EL elements 13R, 13G, and 13B for each pixel, recombination of holes and electrons causes light emission in the respective organic layers 138R, 138G, and 138B. The light may be transmitted, for example, through the second electrode 139, the second barrier film 14, the color filter layers 141R, 141G, and 141B, the overcoat layer 142, the adhesive layer 143, and the second substrate 144 in order to be extracted. Additive color mixture of color light beams thus emitted from the respective pixels allows a color image to be displayed.

In the display unit 1, when moisture enters the organic EL elements 13R, 13G, and 13B or the TFT 131 provided in the element section 13, the characteristics thereof may be deteriorated. Therefore, the element section 13 may be provided on the barrier substrate 10 having a moisture property in the present embodiment. This enables prevention of moisture from entering the element section 13 from the back plane.

In the barrier substrate 10, the inorganic material layer 12A provided on the support substrate 11 prevents permeation of moisture. However, in the inorganic material layer 12A, a defect is more likely to occur in a film due to a film-forming process, e.g., a film-forming process by PECVD method. Thus, moisture may pass thorough the defect, causing the barrier performance to be lowered. Providing the functional layer 12B including an organic material on the inorganic material layer 12A suppresses lowering in the barrier performance due to such a defect in the inorganic material layer 12A.

FIG. 5 illustrates a cross-sectional configuration of a barrier substrate (barrier substrate 100) according to a comparative example of the present embodiment. In the barrier substrate 100, an inorganic material layer 102 and an organic planarization layer 103 may be stacked in this order on a support substrate 101. In the barrier substrate 100, providing the organic planarization layer 103 on the inorganic material layer 102 makes it possible to suppress lowering in the barrier performance due to a defect in a film of the inorganic material layer 102.

However, the organic planarization layer 103 is inferior in adhesion to the inorganic material layer 102, and thus is likely to be detached. In particular, when the barrier substrate 100 goes through a high-temperature process, the organic material to be used for the organic planarization layer 103 may preferably have heat resistance; however, the organic material having such a heat resistance is inferior in the adhesion to the inorganic material layer 102. Therefore, the inorganic material layer 102 and the organic planarization layer 103 are detached from each other, making it difficult to sufficiently achieve the effect brought by providing the organic planarization layer 103, i.e., the effect of suppressing lowering in barrier performance.

In contrast, in the barrier substrate 10 according to the present embodiment, the functional layer 12B provided on the inorganic material layer 12A has the detachment-suppressing function. More specifically, in the present embodiment, the functional layer 12B may include the detachment-suppressing layer 12B1 and the organic planarization layer 12B2 in order from the inorganic material layer 12A. The detachment-suppressing layer 12B1 suppresses the detachment (enhances the adhesion) between the inorganic material layer 12A and the functional layer 12B (organic planarization layer 12B2), thus suppressing the lowering in the barrier performance due to the detachment. In other words, it becomes possible to sufficiently achieve the effect brought by providing the organic planarization layer 12B2 (effect of suppressing lowering in barrier performance).

Further, the detachment-suppressing function of the functional layer 12B makes it possible to use a material having high heat resistance (e.g., polyimide) for the organic planarization layer 12B2, which also makes it possible to enhance the barrier performance owing to the layered structure of the inorganic material layer 12A and the functional layer 12B as well as to improve resistance to the process.

Furthermore, when the support substrate 11 has flexibility, the barrier substrate 10 undergoes bending stress. However, the detachment-suppressing function of the functional layer 12B makes detachment less likely to occur even in the case of bending stress with small curvature radius, thus allowing for enhancement of resistance against the bending stress. Thus, it becomes possible to achieve the barrier substrate 10 and the display unit 1 which are suitable for a flexible display.

In addition, the barrier substrate 10 further including the inorganic material layer 12C on the functional layer 12B makes it possible to achieve a layered structure that makes moisture less likely to permeate therethrough owing to a labyrinth effect. Thus, providing the inorganic material layer 12C makes it possible to improve the barrier performance.

As described above, in the present embodiment, the functional layer 12B containing the organic material is provided on the inorganic material layer 12A provided on the support substrate 11, thus allowing for suppression of lowering in the barrier performance caused by a film property of the inorganic material layer 12A. The functional layer 12B having the detachment-suppressing function, i.e., the functional layer 12B including the detachment-suppressing layer 12B1 makes the inorganic material layer 12A and the functional layer 12B (organic planarization layer 12B2) less likely to be detached from each other, thus allowing for suppression of lowering in the barrier performance due to the detachment. Thus, it becomes possible to further improve the barrier performance.

In the semiconductor device substrate and the display unit according to the embodiment of the disclosure, the first inorganic material layer provided on the substrate prevents permeation of moisture. However, the first inorganic material layer often includes a defect inside a film due to the film-forming process, thus making the barrier performance likely to be lowered. Providing the functional layer containing an organic material on the first inorganic material layer suppresses the lowering in the barrier performance caused by such a defect in the first inorganic material layer. However, the organic material is inferior in adhesion to the first inorganic material layer, and thus is easily detached therefrom. By allowing the functional layer containing the organic material to have the detachment-suppressing function, detachment between the first inorganic material layer and the functional layer is suppressed (adhesion therebetween is enhanced) to suppress the lowering in the barrier performance due to the detachment.

Next, description is given of another embodiment and other modification examples of the disclosure. Hereinafter, the same reference numerals are assigned to components similar to those of the foregoing first embodiment, and description therefor is omitted where appropriate.

### Second Embodiment

FIG. 6 illustrates a cross-sectional configuration of a barrier substrate (barrier substrate 10A) according to a second embodiment of the disclosure. As with the barrier substrate 10 of the foregoing first embodiment, the barrier substrate 10A may be applied as a moisture barrier for the display unit 1 such as an organic EL display or various other semiconductor devices.

As with the barrier substrate 10 of the foregoing first embodiment, the barrier substrate 10A may have roles of supporting the element section 13, and of preventing moisture from entering the element section 13. The barrier substrate 10A may have a layered film including, on the support substrate 11, for example, the inorganic material layer 12A, an organic planarization layer 12B3 (functional layer, second organic planarization layer), and the inorganic material layer 12C, as the first barrier film 12, in this order.

The organic planarization layer 12B3 may be a functional layer that is made of an organic material and has a detachment-suppressing function. The organic planarization layer 12B3 is configured to planarize a surface of the inorganic material layer 12A and to suppress detachment from the inorganic material layer 12A (to enhance adhesion to the inorganic material layer 12A).

An organic material to be used for the organic planarization layer 12B3 may preferably have heat resistance. This is because the organic material may go through a high-temperature process in a step of forming the above-described element section 13, for example, when forming the element section 13 on the barrier substrate 10A, as with the barrier substrate 10 in the foregoing first embodiment. Also in the organic planarization layer 12B3, it is possible to suitably use polyimide, for example, as an organic material having high heat resistance.

In the present embodiment, the organic planarization layer 12B3 may contain silicon (Si). More specifically, the organic planarization layer 12B3 may contain a silane compound that has a reactive functional group and a hydrolytic group. The reactive functional group reacts with the above-mentioned organic material (e.g., polyimide). The hydrolytic group forms a chemical bonding with the surface of the inorganic material layer 12A. Examples of such a silane compound may include a silane coupling agent. This enables the organic planarization layer 12B3 to enhance adhesion to the inorganic material layer 12A.

The organic planarization layer 12B3 may have a thickness in a range from 5 μm to 20 μm, for example.

In the barrier substrate 10A according to the present embodiment, the organic planarization layer 12B3 provided on the inorganic material layer 12A has the detachment-suppressing function. More specifically, in the present embodiment, the organic planarization layer 12B3 may be made of an organic material and silicon. This suppresses the detachment (enhances the adhesion) between the inorganic material layer 12A and the organic planarization layer 12B3, thus suppressing the lowering in the barrier performance due to the detachment. Therefore, it becomes possible to achieve effects similar to those of the foregoing first embodiment.

Further, the detachment-suppressing function of the organic planarization layer 12B3 makes it possible to use a material having high heat resistance (e.g., polyimide) for the organic planarization layer 12B3, which also makes it possible to enhance the barrier performance owing to the layered structure of the inorganic material layer 12A and the organic planarization layer 12B3 as well as to improve resistance to the process, as with the foregoing first embodiment.

Furthermore, when the support substrate 11 has flexibility, the barrier substrate 10A undergoes bending stress. However, the detachment-suppressing function of the organic planarization layer 12B3 makes it possible to enhance resistance against such bending stress. Thus, it becomes possible to achieve the barrier substrate 10A suitable for a flexible display, as with the foregoing first embodiment.

In addition, the barrier substrate 10A further including the inorganic material layer 12C on the organic planarization layer 12B3 makes it possible to achieve a layered structure that makes moisture less likely to permeate therethrough owing to a labyrinth effect. Thus, providing the inorganic material layer 12C makes it possible to further improve the barrier performance, as with the foregoing first embodiment.

Further, in the present embodiment, it is sufficient to only add, for example, the silane coupling agent to an organic material in forming the organic planarization layer 12B3, thus making it possible to reduce film-forming processes, as compared to the foregoing first embodiment.

### Modification Example 1

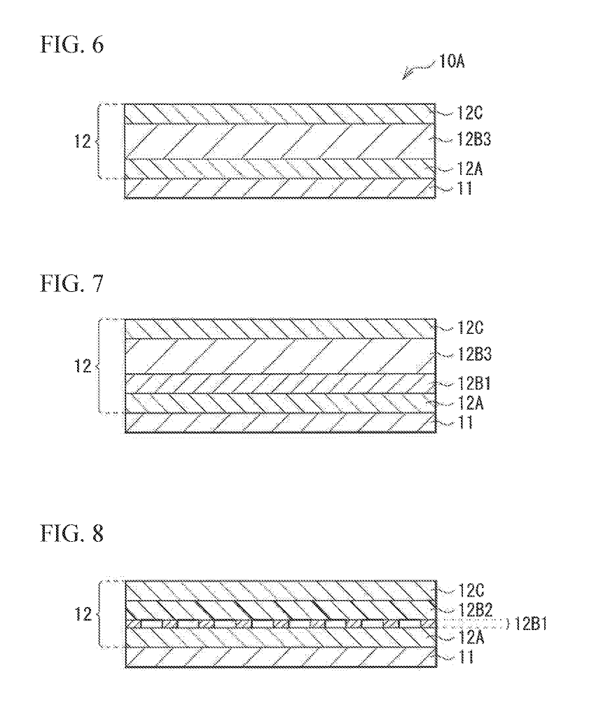

FIG. 7 illustrates a cross-sectional configuration of a barrier substrate according to Modification Example 1. Description has been given, in the foregoing embodiments of the disclosure, of a case where the functional layer is a layered film including the detachment-suppressing layer 12B1 and the organic planarization layer 12B2, and of a case where the functional layer is the organic planarization layer 12B3 containing silicon. However, the configuration of the functional layer is not limited thereto. For example, as in the present modification example, a layered film containing, as the functional layer, the detachment-suppressing layer 12B1 and the organic planarization layer 12B3 containing silicon may also be used. The barrier substrate of the present modification example may have a configuration in which the detachment-suppressing layer 12B1, the organic planarization layer 12B3, and the inorganic material layer 12C are stacked in this order on the inorganic material layer 12A in the first barrier film 12 provided on the support substrate 11.

In the present modification example, by providing, on the inorganic material layer 12A, the detachment-suppressing layer 12B1 and the organic planarization layer 12B3 containing silicon, it becomes possible to suppress the detachment of the inorganic material layer 12A and the organic planarization layer 12B3 from each other. Therefore, it is possible to achieve effects similar to those of the foregoing first embodiment. Further, the detachment-suppressing layer 12B1 and the organic planarization layer 12B3 both having the detachment-suppressing function make it possible to achieve firmer adhesion than that in any of the foregoing first and second embodiments.

### Modification Example 2

FIG. 8 illustrates a cross-sectional configuration of a barrier substrate according to Modification Example 2. The foregoing first embodiment exemplifies the configuration in which the detachment-suppressing layer 12B1 in the functional layer 12B is provided throughout the entire surface of the inorganic material layer 12A. However, it is also possible to provide the detachment-suppressing layer 12B1 only in selective regions on the inorganic material layer 12A as in the present modification example. More specifically, it is possible to provide the detachment-suppressing layer 12B1 separately, e.g., in a plurality of regions on the inorganic material layer 12A, for example. Alternatively, the detachment-suppressing layer 12B1 may also be provided either only at an end portion, i.e., at a peripheral portion of the surface of the inorganic material layer 12A, or in selective regions including the end portion.

Even when the detachment-suppressing layer 12B1 is provided only in the selective regions as described in the present modification example, it is possible to suppress the detachment of the inorganic material layer 12A and the organic planarization layer 12B2 from each other, thus making it possible to achieve effects substantially similar to those of the foregoing first embodiment. In order to further enhance the adhesion as well as to improve the barrier performance, however, it may be preferable to provide the detachment-suppressing layer 12B1 throughout the entire surface of the inorganic material layer 12A.

### Modification Example 3

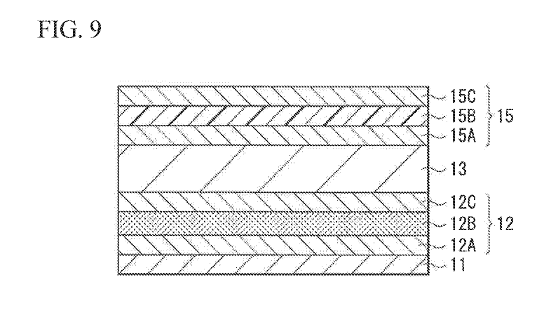

FIG. 9 illustrates a cross-sectional configuration of a display unit according to Modification Example 3. The display unit 1 of the foregoing first embodiment exemplifies the configuration in which the second barrier film 14 is provided inside the element section 13. However, the second barrier film (second barrier film 15) may also be provided on the element section 13 as in the present modification example. That is, in the present modification example, the element section 13 may be provided between the barrier substrate 10 and the second barrier film 15. The barrier substrate 10 includes the first barrier film 12. Layers of the second barrier film 15 may be formed sequentially on the element section 13 (more particularly, on the second substrate 144), for example.

The second barrier film 15 may include, for example, an inorganic material layer 15A (third inorganic material layer), an organic planarization layer 15B (third organic planarization layer), and an inorganic material layer 15C (fourth inorganic material layer), in order from the element section 13.

The inorganic material layers 15A and 15C may be each made of an inorganic material having a moisture barrier property, for example, silicon oxide, silicon nitride, silicon oxynitride, and aluminum oxide, as with the inorganic material layer 12A of the foregoing first embodiment. The materials and the thicknesses of the inorganic material layers 15A and 15C either may be the same as or different from each other. Further, the inorganic material layer 15C may not necessarily be provided; however, providing the inorganic material layers 15A and 15C with the organic planarization layer 15B being interposed therebetween makes it possible to further enhance a barrier performance in the second barrier film 15.

The organic planarization layer 15B may be made of an organic material. Here, the second barrier film 15 may be formed after formation of the element section 13. Therefore, it is not questioned whether the material has heat resistance for the organic planarization layer 15B of the second barrier film 15, unlike the organic planarization layer 12B2 of the first barrier film 12. Consequently, the organic planarization layer 15B has higher degree of freedom of material choice than that of the organic planarization layer 12B2.

The second barrier film 15 may be provided above the element section 13 as in the present modification example. Also in this case, it is possible to achieve effects similar to those of the foregoing first embodiment.

Although the description has been given hereinabove by way of example with reference to the embodiments and modification examples, the disclosure is not limited thereto, but may be modified in a wide variety of ways. The materials and thicknesses of respective layers, as well as film-forming methods and film-forming conditions described in the foregoing embodiments and modification examples are not limitative; other materials and thicknesses may also be adopted, and other film-forming methods and film-forming conditions may also be adopted.

It is to be noted that the effects described herein are mere examples and are not limited thereto, and may include other effects.

Moreover, the disclosure may also have the following configurations.

(1)

A semiconductor device substrate including:

a substrate;

a first inorganic material layer provided on the substrate and having a moisture barrier property; and

a functional layer provided on the first inorganic material layer, the functional layer containing an organic material and having a detachment-suppressing function.

(2)

The semiconductor device substrate according to (1), wherein the functional layer includes, in order from the first inorganic material layer:

a detachment-suppressing layer containing one or both of metal and metal oxide; and

a first organic planarization layer containing the organic material.

(3)

The semiconductor device substrate according to (2), wherein the detachment-suppressing layer contains one or more of titanium, titanium oxide, aluminum, aluminum oxide, indium-zinc oxide, and indium-tin oxide.

(4)

The semiconductor device substrate according to (2) or (3), wherein

the detachment-suppressing layer is configured by a metal film, and

the detachment-suppressing layer has a thickness of 10 nm or less.

(5)

The semiconductor device substrate according to (1), wherein the functional layer includes a second organic planarization layer containing the organic material and silicon.

(6)

The semiconductor device substrate according to (5), wherein the second organic planarization layer contains a silane coupling agent.

(7)

The semiconductor device substrate according to (1), wherein the functional layer includes, in order from the first inorganic material layer:

a detachment-suppressing layer containing one or both of metal and metal oxide; and

a second organic planarization layer containing the organic material and silicon.

(8)

The semiconductor device substrate according to any one of (1) to (7), wherein the organic material has heat resistance.

(9)

The semiconductor device substrate according to (8), wherein the organic material includes polyimide.

(10)

The semiconductor device substrate according to any one of (1) to (9), further including a second inorganic material layer provided on the functional layer, the second inorganic material layer having the moisture barrier property.

(11)

The semiconductor device substrate according to any one of (1) to (10), wherein the substrate has flexibility.

(12)

A display unit including:

a substrate;

a first barrier film provided on the substrate and having a moisture barrier property, the first barrier film including, in order from the substrate,
a first inorganic material layer having the moisture barrier property, and
a functional layer provided on the first inorganic material layer, the functional layer containing an organic material and having a detachment-suppressing function; and

an element section provided on the first barrier film and including a plurality of pixels.

(13)

The display unit according to (12), wherein the functional layer includes, in order from the first inorganic material layer:

a detachment-suppressing layer containing one or both of metal and metal oxide; and

a first organic planarization layer containing the organic material.

(14)

The display unit according to (12), wherein the functional layer includes a second organic planarization layer containing the organic material and silicon.

(15)

The display unit according to (12), wherein the functional layer includes, in order from the first inorganic material layer:

a detachment-suppressing layer containing one or both of metal and metal oxide; and

a second organic planarization layer containing the organic material and silicon.

(16)

The display unit according to any one of (12) to (15), wherein the first barrier film further includes a second inorganic material layer provided on the functional layer and having the moisture barrier property.

(17)

The display unit according to any one of (12) to (16), further including a second barrier film provided inside or above the element section and having the moisture barrier property.

(18)

The display unit according to (17), wherein the second barrier film includes, in order from the substrate,
a third inorganic material layer having the moisture barrier property,
a third organic planarization layer containing an organic material, and
a fourth inorganic material layer having the moisture barrier property.

It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor device substrate comprising:
a substrate;
a first inorganic material layer provided on the substrate and having a moisture barrier property; and
a functional layer provided on the first inorganic material layer, the functional layer containing an organic material and having a detachment-suppressing function.

2. The semiconductor device substrate according to claim 1, wherein the functional layer includes, in order from the first inorganic material layer:
a detachment-suppressing layer containing one or both of metal and metal oxide; and
a first organic planarization layer containing the organic material.

3. The semiconductor device substrate according to claim 2, wherein the detachment-suppressing layer contains one or more of titanium, titanium oxide, aluminum, aluminum oxide, indium-zinc oxide, and indium-tin oxide.

4. The semiconductor device substrate according to claim 2, wherein
the detachment-suppressing layer is configured by a metal film, and
the detachment-suppressing layer has a thickness of 10 nm or less.

5. The semiconductor device substrate according to claim 1, wherein the functional layer comprises a second organic planarization layer containing the organic material and silicon.

6. The semiconductor device substrate according to claim 5, wherein the second organic planarization layer contains a silane coupling agent.

7. The semiconductor device substrate according to claim 1, wherein the functional layer includes, in order from the first inorganic material layer:
a detachment-suppressing layer containing one or both of metal and metal oxide; and
a second organic planarization layer containing the organic material and silicon.

8. The semiconductor device substrate according to claim 1, wherein the organic material has heat resistance.

9. The semiconductor device substrate according to claim 8, wherein the organic material comprises polyimide.

10. The semiconductor device substrate according to claim 1, further comprising a second inorganic material layer provided on the functional layer, the second inorganic material layer having the moisture barrier property.

11. The semiconductor device substrate according to claim 1, wherein the substrate has flexibility.

12. A display unit comprising:
a substrate;
a first barrier film provided on the substrate and having a moisture barrier property, the first barrier film including, in order from the substrate,
a first inorganic material layer having the moisture barrier property, and
a functional layer provided on the first inorganic material layer, the functional layer containing an organic material and having a detachment-suppressing function; and
an element section provided on the first barrier film and including a plurality of pixels.

13. The display unit according to claim 12, wherein the functional layer includes, in order from the first inorganic material layer:
a detachment-suppressing layer containing one or both of metal and metal oxide; and
a first organic planarization layer containing the organic material.

14. The display unit according to claim 12, wherein the functional layer comprises a second organic planarization layer containing the organic material and silicon.

15. The display unit according to claim 12, wherein the functional layer includes, in order from the first inorganic material layer:
a detachment-suppressing layer containing one or both of metal and metal oxide; and
a second organic planarization layer containing the organic material and silicon.

16. The display unit according to claim 12, wherein the first barrier film further includes a second inorganic material layer provided on the functional layer and having the moisture barrier property.

17. The display unit according to claim 12, further comprising a second barrier film provided inside or above the element section and having the moisture barrier property.

18. The display unit according to claim 17, wherein the second barrier film includes, in order from the substrate,
a third inorganic material layer having the moisture barrier property,
a third organic planarization layer containing an organic material, and
a fourth inorganic material layer having the moisture barrier property.
